(19) United States
(12) Patent Application Publication
(10) Pub. No.: US 2023/0031682 A1
(43) Pub. Date: Feb. 2, 2023

(54) METHOD OF MANUFACTURING SUBSTRATES FOR SEMICONDUCTOR DEVICES, CORRESPONDING SUBSTRATE AND SEMICONDUCTOR DEVICE

(71) Applicant: STMicroelectronics S.r.l., Agrate Brianza (MB) (IT)

(72) Inventor: Mauro MAZZOLA, Calvenzano (BERGAMO) (IT)

(73) Assignee: STMicroelectronics S.r.l., Agrate Brianza (MB) (IT)

(21) Appl. No.: 17/870,455

(22) Filed: Jul. 21, 2022

(30) Foreign Application Priority Data
Jul. 28, 2021 (IT) 102021000020111

(51) Int. Cl. H01L 23/495; H01L 23/00; H01L 21/56

(52) U.S. Cl. CPC H01L 23/49503; H01L 23/49575; H01L 23/49555; H01L 23/49582; H01L 24/48; H01L 21/565; H01L 2224/48247

(57) ABSTRACT

A pre-molded substrate for semiconductor devices includes a sculptured electrically conductive (e.g., copper) laminar structure having spaces therein. The laminar structure includes one or more die pads having a first die pad surface configured to have semiconductor chips mounted thereon. A pre-mold material molded onto the laminar structure penetrates into the spaces therein and provides a laminar pre-molded substrate including the first die pad surface left exposed by the pre-mold material with the die pad(s) bordering on the pre-mold material. One or more stress-relief curved portions are provided at the periphery of one or more of the die pads. The stress-relief curved portions are configured to border on the pre-mold material over a smooth surface to effectively counter the formation of cracks in the pre-mold material as a result of the pre-molded substrate being bent.

### PRIORITY CLAIM

This application claims the priority benefit of Italian Application for Patent No. 102021000020111, filed on Jul. 28, 2021, the content of which is hereby incorporated by reference in its entirety to the maximum extent allowable by law.

### TECHNICAL FIELD

The description relates to semiconductor devices.

One or more embodiments can be applied to semiconductor power devices for the automotive sector, for instance.

### BACKGROUND

In substrates such as pre-molded leadframes, adequate adhesion between the sculptured, electrically conductive structure of the leadframe (copper, for instance) and the pre-mold resin (an epoxy resin, for instance) molded thereon should desirably absorb stresses generated if the pre-molded leadframe is pressed or bent, thus countering the formation of cracks which may also propagate along the leadframe.

It is noted that stress, and thus the risk of cracks being generated, increases in the case of narrow strips of pre-mold material.

There is a need in the art to deal with the issues as discussed in the foregoing.

### SUMMARY

One or more embodiments relate to a method.

One or more embodiments relate to a corresponding substrate (leadframe) for semiconductor devices.

One or more embodiments relate to a semiconductor device.

One or more embodiments rely on a modification of die pad shape, optionally at the front or top side only, of a substrate such as a leadframe.

In certain examples, a lateral half-etched stress-relief (or stress-reducing) protrusion is created in a die pad leaving the bottom side of the die pad straight.

Such a shape facilitates absorbing stresses that are generated in response to the substrate (leadframe) being bend or possibly pressed during wire bonding, for instance.

One or more embodiments facilitate producing smaller semiconductor device packages.

### BRIEF DESCRIPTION OF THE DRAWINGS

One or more embodiments will now be described, by way of example only, with reference to the annexed figures, wherein:

FIG. 1 is exemplary of the possible formation of cracks in a substrate such as a pre-molded leadframe;

FIG. 2 is a plan view of a pre-molded leadframe highlighting areas more exposed to the formation of cracks;

FIG. 3 is exemplary of measures that can be attempted in order to counter the formation of cracks in pre-molded leadframes;

FIGS. 4A and 4B are plan views of pre-molded leadframes illustrative of possible topologies exposed to the formation of cracks;

FIGS. 5A and 5B are illustrative of a pre-molded leadframe according to embodiments of the present description;

FIG. 6 is a view of the portion of FIG. 5A indicated by arrow VI reproduced on an enlarged scale;

FIGS. 7 and 8 are cross-sectional views along lines VII-VII and line VIII-VIII in FIG. 6, respectively, reproduced on a further enlarged scale;

FIG. 9 is a view of a portion of leadframe like the portion illustrated in FIG. 6, showing possible advantageous features of embodiments;

FIG. 10 is a cross-sectional view along line X-X of FIG. 9 reproduced on a further enlarged scale; and

FIGS. 11 and 12 are plan views (front and back) of a pre-molded leadframe according to embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Semiconductor devices may comprise one or more semiconductor integrated circuit chips or dice arranged (attached) on substrates such as leadframes.

Plastic packages are commonly used for semiconductor devices. Such packages may include a leadframe providing a base substrate comprising electrically conductive material such as copper, sized and shaped to accommodate semiconductor chips or dice and providing pad connections (leads) for these chips or dice.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

Substrates such as leadframes are advantageously provided in a pre-molded version wherein an insulating resin (an epoxy resin, for instance) fills the empty spaces between the die pads and leads.

A pre-molded leadframe is a thus a laminar substrate that is substantially flat with the pre-mold material (resin) filling the spaces in the electrically conductive structure (of metal material such as copper, for instance) of the leadframe, that has been bestowed a sculptured appearance including empty spaces during forming, by etching, for instance.

The total thickness of the pre-mold leadframe is the same thickness of the sculptured electrically conductive structure.

During the assembly process of semiconductor devices using pre-molded leadframe, a pre-molded leadframe can be exposed to repeated stress.

For instance, during handling or when deposited in a slot magazine the leadframe could be bent merely due to its weight.

Also, during wire bonding, the leadframe is subject to clamping and the bonding tools that place the bonding wires or ribbons may further stress the leadframe structure.

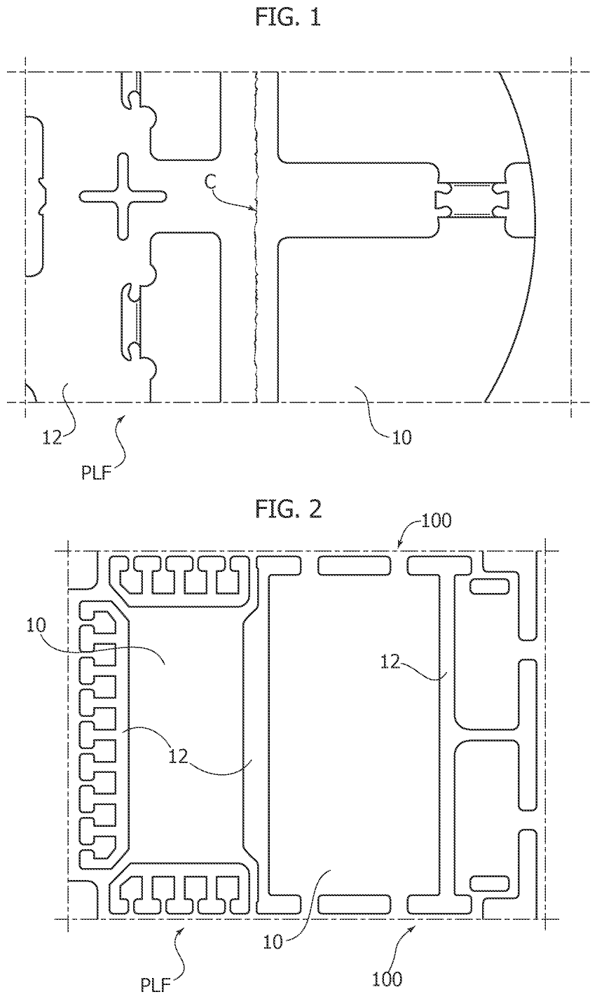

FIG. 1 is exemplary of a crack C possibly formed in a pre-molded leadframe illustrated as comprising, in general, electrically conductive (metal, e.g., copper) portions 10 included in a sculptured, electrically conductive structure of the leadframe, having spaces filled by the pre-mold material (resin) 12.

For instance, as depicted in FIG. 1, in response to the pre-mold leadframe being bent, a crack C can be formed in the resin 12 with the crack likely to propagate along an elongated portion of the pre-mold material 12.

The presence of such cracks is a source of material rejection.

The plan view of FIG. 2 shows that the formation and propagation of cracks may be related to the fact that in certain pre-molded leadframe topologies, two sides connected by connecting bars 100 may represent the sole portions of the leadframe resisting flexural stresses.

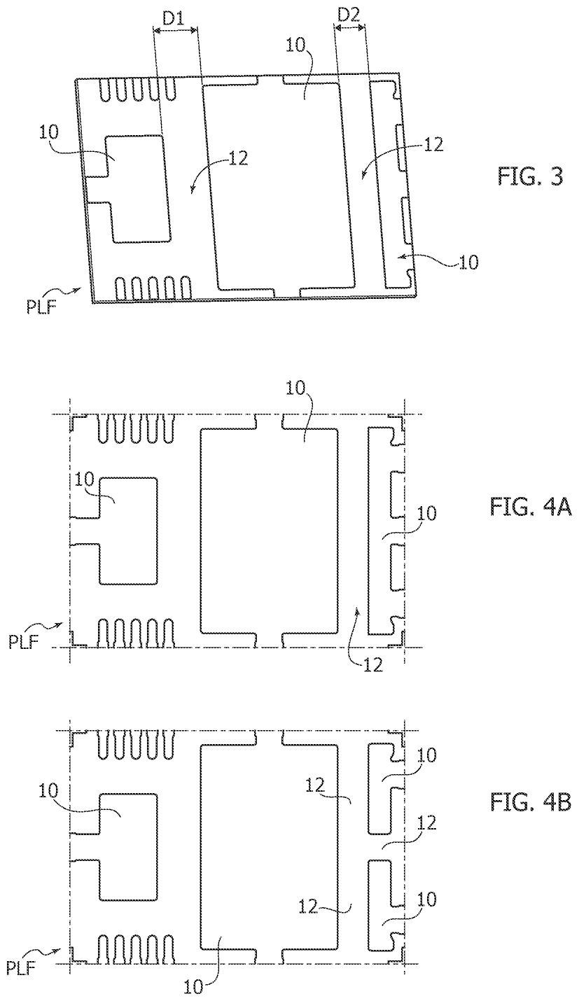

FIG. 3 is exemplary of the trend towards an increasingly high number of devices being hosted onto a leadframe PLF in order to decrease the cost of the associated units while reducing the package size.

Reducing package size may involve reducing the spacing between adjacent conductive portions of the pre-molded leadframes such as die pads 10. This in turn translates into reducing the width (see, for instance, D1 and D2 in FIG. 3) of the portions of pre-mold material 12 included therebetween.

The pre-mold material 12 between adjacent die pads 10 may thus be reduced to very narrow straight lines. Reducing widths such as D1 and D2 makes the pre-mold material (resin) more fragile.

The pre-mold material 12 is thus more easily exposed to the formation of cracks if the leadframe PLF is bent, pressed or pulled, with the risk that such cracks can easily expand (propagate) over the whole surface of the leadframe.

FIGS. 4A and 4B facilitate understanding that the risk of formation and propagation of cracks may exist both in rectilinear areas of the pre-mold material (such as the one indicated at 12 in FIG. 4A, which refers to a single-channel power Quad-Flat No-leads or QFN package) and, even more, in those areas where of the pre-mold material 12 exhibits more complex shapes such as a T-shape as indicated by plural references 12 in FIG. 4B (which refers to a dual-channel power QFN package)

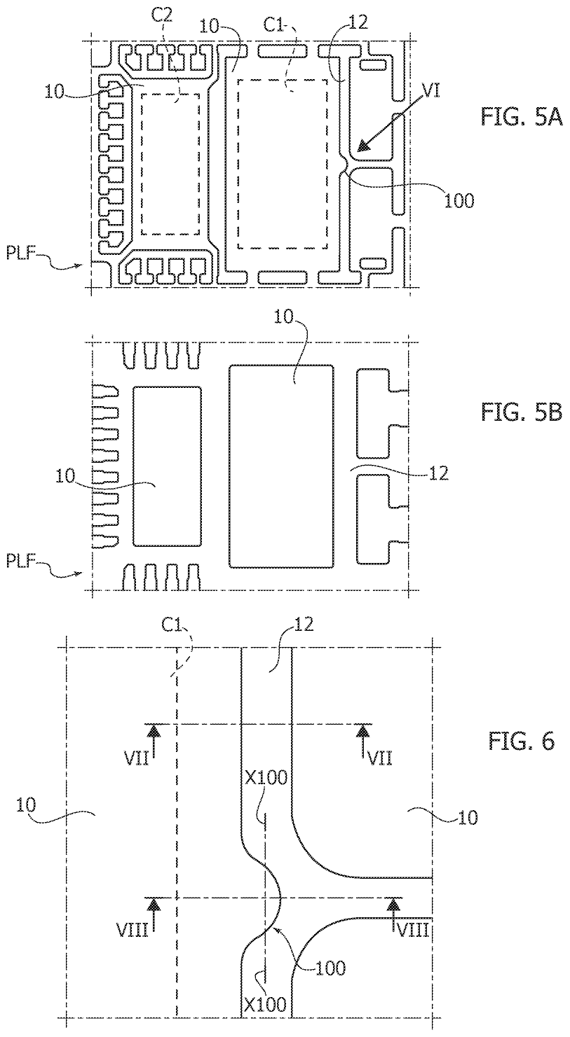

FIGS. 5A and 5B are plan views of a pre-molded leadframe PLF.

FIG. 5A reproduces the level of the front or top surface of the leadframe PLF, where one or more semiconductor chips or dice C1, C2 (shown in dashed outline) are intended to be mounted at the front or top surfaces of respective die pads 10.

FIG. 5B is a plan views of the same pre-molded leadframe PLF at the level of the back or bottom surface, where the die pads 10 may be exposed, that is left uncovered by the pre-mold material 12 (this may facilitate, for instance, dissipation of the heat generated by the chips C1, C2 during operation).

It is noted that FIGS. 5A and 5B refer to a leadframe topology as exemplified in

FIG. 4B (dual channel pads intended to be coupled with respective ribbons, not visible in the figures) which is regarded as particularly critical insofar as the formation of cracks is concerned.

It will be otherwise appreciated that FIGS. 5A and 5B (and the subsequent figures as well) are exemplary of pre-molded leadframes including, as otherwise conventional in the art, a sculptured, electrically conductive laminar structure having (originally empty) spaces therein and a pre-mold material (such as a resin 12) molded onto the laminar structure and filling those spaces.

The pre-mold material penetrates into the spaces in the sculptured, electrically conductive structure to provide, once solidified (via UV or heat curing, for instance) a laminar pre-molded substrate PLF.

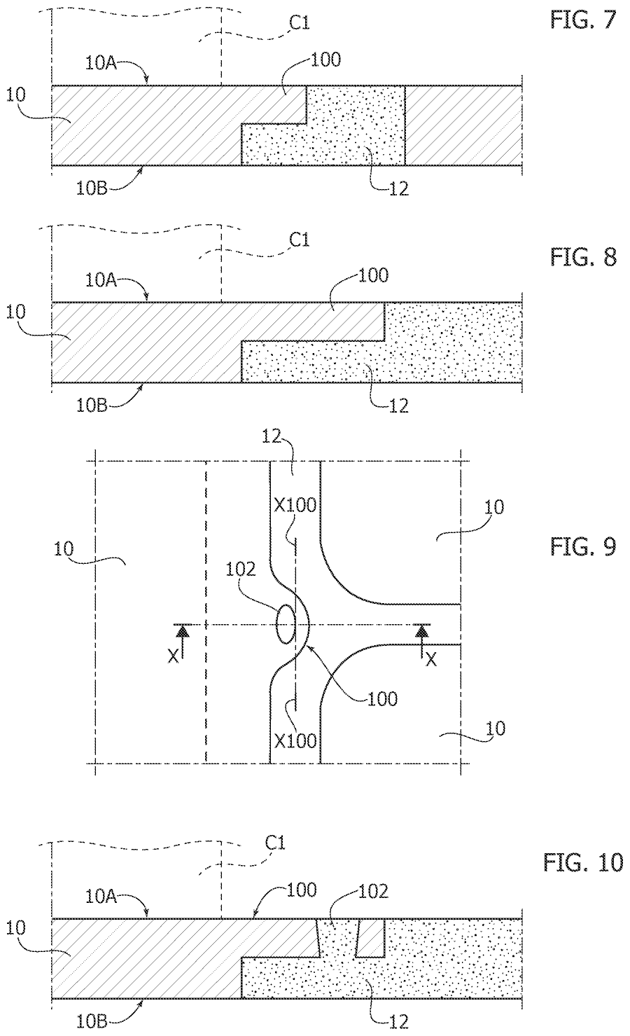

As illustrated, such a sculptured, electrically conductive laminar structure comprises, in addition to other features that will not be discussed here for simplicity, one or more die pads 10. With reference to FIGS. 7, 8 and 10, the die pads 10 include: a first, front or top, die pad surface 10A intended to be left exposed, that is uncovered, by the pre-mold material 12 to facilitate mounting one or more semiconductor chips or dice C1, C2 thereon, and a second, back or bottom surface 10B, opposite the front or top surface 10A, where the die pads 10 may be left likewise exposed, that is uncovered, by the pre-mold material 12.

As used therein, “may” highlights the fact that, in certain embodiments, one or more of the die pads 10 may be die pads having a thickness that is less (half, for instance, hence the current “half-etched” definition) than the overall thickness of the pre-molded leadframe.

In that way, the “half-etched” die pad or pads will be covered at their back surfaces 10B by the (electrically insulating) pre-mold material 12 giving rise to insulated die pads.

Whatever the details of implementation, in pre-mold leadframes PLF as exemplified herein, the die pads 10 have their periphery (that is, the sides) bordering on (a strip of) the pre-mold material 12 molded onto the laminar structure of the leadframe.

In solutions as exemplified in FIGS. 1 to 4B, the die pads 10 are rectangular pads that border on the pre-mold material 12 along rectilinear border lines throughout (with slightly rounded tip portions, at most).

Even without wishing to be bound to any specific theory in that respect, these rectilinear borderlines are found to be at the basis of the formation (and propagation) of cracks such as the crack C illustrated in FIG. 1.

The examples presented in FIGS. 5A-12 contemplate providing at the periphery of one or more die pads, optionally (only) at the first die pad surface 10A, at least one stress-relief (or stress-reducing) curved portion 100 configured to border on the pre-mold material 12 over a (lateral) rounded surface, that is over a smooth, curved surface (that is, an even and regular surface free from perceptible projections, lumps, or indentations).

As exemplified in FIG. 6, the stress-relief curved portion 100 may comprise, e.g., a protrusion of the die pad 10 extending into the pre-mold material 12.

As visible, e.g., in FIG. 6, the stress-relief portion 100 may exhibit, when observed in a plan view, a profile which can be regarded as a serpentine, at least approximately sinusoidal trajectory with respect to a reference median line X100 parallel to the (otherwise rectilinear) side of the die pad 10.

That is, the stress-relief curved portion 100 extends in the plane of the laminar pre-molded substrate PLF (the thickness thereof is de facto negligible) along an approximately sinusoidal trajectory.

Again, without wishing to be bound to any specific theory in that respect, such an approximately sinusoidal shape was found to be particularly effective in countering possible formation and propagation of cracks.

As appreciable in FIG. 6, for instance, the stress-relief curved portion 100 is advantageously located at the same location where the pre-mold material 12 fills a T-shaped (originally) empty space in the sculptured electrically conductive structure of the leadframe.

As visible in FIG. 6, in the case of stress-relief curved portion 100 formed by a protrusion of the leadframe 10, this results in turning what was a T-shaped space (see FIG. 4B) intended to be filled by the pre-mold material 12 into a Y-shaped space with rounded edges.

Such a curved shape was felt to be particularly effective in absorbing stresses originating when the leadframe PLF is bent or pressed (during wire bonding, for instance).

This result was found to be particularly advantageous in those cases where the (straight) resin portion is more than 50% of the package width.

FIGS. 9 and 10 are exemplary of arrangements where the stress-relief curved portion 100 is a protrusion traversed by (e.g., has formed therein) a through-hole 102 that (see, e.g., FIG. 10) is filled by the pre-mold material 12.

This arrangement was found to be particularly effective in providing a strong locking between the sculptured structure of the leadframe (die pads 10) and the pre-mold material 12 filling the spaces therein.

Advantageously, rather than a round hole, the hole 102 may be an elongated hole (a buttonhole) having a major dimension in the direction of the side of the leadframe 10.

Also, as visible in FIG. 10, the hole 102 may present a slightly tapered shape starting from the front pad surface 10A. Such shape can be advantageously provided during forming the sculptured structure of the leadframe via etching.

Advantageously, as visible in figures such as FIGS. 8 and 10, the stress-relief curved portion 100 (a recess or, advantageously, a protrusion) can be provided only adjacent one of the opposed surfaces 10A, 10B of the die pad 10.

For instance, as illustrated herein, the stress-relief curved portion(s) 100 can be provided only at the front or top pad surface 10A, while the opposite surface (here, the back or bottom pad surface 10B opposite the front or top surface 10A) retains a generally rectilinear shape.

In certain embodiments, a complementary option can be adopted with the stress-relief curved portion(s) 100 provided only at the back or bottom pad surface 10B, while the front or top surface 10A retains a generally rectilinear shape.

In certain embodiments, the stress-relief curved portion(s) 100 can be provided over the whole thickness of the die pad, that is both at the front or top pad surface 10A and at the back or bottom pad surface 10B.

The foregoing applies irrespective of the fact that one or more holes such as 102 are provided in the stress-relief portion 100.

Figures such as FIG. 7 also illustrate that the periphery of die pads such as 10 may have a stepped profile, with the front or top surface 10A larger than (and thus protruding with respect to) the back or bottom surface 10B.

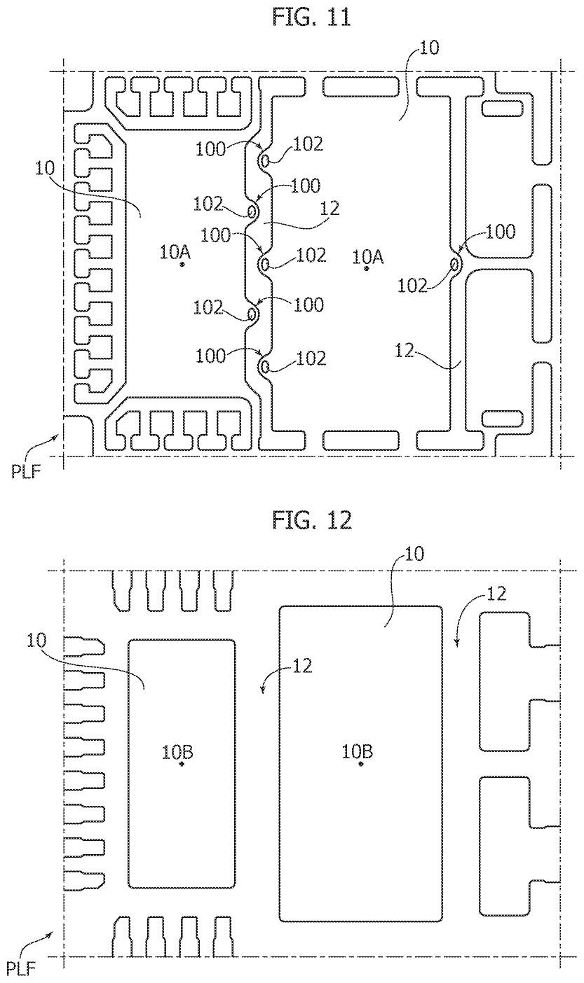

FIGS. 11 and 12 are further views of a pre-molded leadframe PLF at the level of the front or top surfaces 10A of die pads 10 provided therein and at the level of the back or bottom surface 10B of the die pads 10.

FIGS. 11 and 12 are exemplary of the possibility of providing one or more stress-relief curved portions 100 only adjacent the front die pad surface 10A while the sides of the back or bottom surfaces 10B (see FIG. 12) retain a substantially rectilinear shape.

FIG. 11 is also exemplary of the possibility of providing one or more stress-relief curved portion 100 (with or without holes 102) at plural locations in a leadframe.

For instance, the die pad 10 in a central position in FIG. 11 has stress-relief curved portions 100 at both its major (longer) sides, which are vertical in the figure.

Also, FIG. 11 is exemplary of the possibility of providing plural adjacent stress-relief curved portions 100 (again with or without holes 102) at a certain side of a leadframe.

Again, the die pad 10 in a central position in FIG. 11 has a plurality of stress-relief curved portions 100 at its major (longer) side on the left and a single stress-relief curved portion 100 at its major (longer) side on the right.

For instance, in certain embodiments, a die pad 10 may have: a single stress-relief curved portion 100 at one or more of its sides (a single portion 100 at each side); and/or plural stress-relief curved portions 100 at one or more of its sides (plural portions 100 at each side); and/or single and/or plural stress-relief curved portions 100 at all or just a part of its sides (e.g., a combination of the foregoing).

FIG. 11 is also exemplary of the possibility of providing at mutually facing sides of neighboring die pads 10 having a strip of pre-mold material 12 extending therebetween, plural stress-relief curved portions 100 at mutually facing sides of two neighboring pads 10.

As illustrated in FIG. 11, these plural stress-relief curved portions 100 in the mutually facing sides of neighboring die pads 10 can be provided as an alternation of (e.g., interdigitated) stress-relief curved portions 100 (protrusions, for instance) so that the strip of pre-mold material 12 therebetween has a general zigzag or serpentine pattern.

Arrangements as exemplified herein were found to facilitate larger adhesion surfaces to lock the pre-mold material 12 to the die pads 10, with the curvy boundary line therebetween provided by formations such as 100 being effective in absorbing stresses and countering the formation and propagation of crash therebetween.

Also, stress-relief formations 100 in the form of protrusions were found to be beneficial in facilitating a pre-mold material flow to a perpendicular channel (see, for instance, visible in FIGS. 6 and 9) while also facilitating (especially when holes such 102 are provided) a stronger locking of the electrically conductive and the insulating (electrically non-conductive) parts of the pre-mold leadframe.

Advantageously, in packages with the dual channel pads or channels perpendicular to a die pad (see again FIGS. 6 and 9: these were found to be particularly exposed to crack formation) the pre-mold material 12 does not follow a straight line and has a perpendicular portion.

The curved shape of a stress-relief formation at such a point absorbs significantly the stresses developed when the leadframe is bent or pressed (during wire bonding, for instance).

As noted, such a modification of the boundary of the die pad may occur only at one of the front surface 10A and the back surface 10B, e.g., only at the front surface 10A.

Without prejudice to the underlying principles, the details and embodiments may vary, even significantly, with respect to what has been described in the foregoing, by way of example only, without departing from the extent of protection.

The claims are an integral part of the technical teaching provided herein with reference to the embodiments.

The extent of protection is determined by the annexed claims.

1. A method, comprising:
providing a sculptured electrically conductive laminar structure having spaces therein, wherein the sculptured electrically conductive laminar structure includes at least one die pad having a first die pad surface configured for mounting a semiconductor chip; and
molding pre-mold material to penetrate into said spaces of the sculptured electrically conductive laminar structure and produce a laminar pre-molded substrate including said first die pad surface left exposed by the pre-mold material with a periphery of the at least one die pad bordering on the pre-mold material;
wherein providing the sculptured electrically conductive laminar structure comprises providing at the periphery of the at least one die pad at least one stress-relief curved portion configured to border on the pre-mold material molded onto the sculptured electrically conductive laminar structure over a smooth surface.

2. The method of claim 1, wherein the at least one stress-relief curved portion extends in a plane of the laminar pre-molded substrate along an approximately sinusoidal trajectory.

3. The method of claim 1, wherein the at least one stress-relief curved portion comprises a protrusion extending into the pre-mold material molded onto the sculptured electrically conductive laminar structure.

4. The method of claim 3, further comprising providing in said protrusion at least one aperture configured to be filled by the pre-mold material molded onto the sculptured electrically conductive laminar structure.

5. The method of claim 1, further comprising providing said at least one stress-relief curved portion at a location of said sculptured electrically conductive laminar structure wherein a T-shaped space is provided for filling by the pre-mold material molded onto the sculptured electrically conductive laminar structure.

6. The method of claim 1, wherein the at least one die pad of the sculptured electrically conductive laminar structure comprises a pair of neighboring die pads having a strip of pre-mold material therebetween, and wherein providing the sculptured electrically conductive laminar structure comprises forming in said pair of neighboring die pads an alternation of said stress-relief curved portions.

7. The method of claim 1, wherein the at least one die pad of the sculptured electrically conductive laminar structure comprises a pair of neighboring die pads having a strip of pre-mold material therebetween, and wherein providing the sculptured electrically conductive laminar structure comprises forming in said pair of neighboring die pads interdigitated stress-relief curved protrusions, and wherein said strip of pre-mold material therebetween has a serpentine pattern.

8. The method of claim 1, wherein the at least one die pad has a second die pad surface opposite said first die pad surface and wherein providing the sculptured electrically conductive laminar structure comprises providing the at least one stress-relief curved portion at only one of the first die pad surface and the second die pad surface.

9. The method of claim 8, wherein the periphery of the other of the first die pad surface and the second die pad surface, opposite said at least one stress-relief curved portion, is rectilinear.

10. A substrate, comprising:
a sculptured electrically conductive laminar structure having spaces therein, the sculptured electrically conductive laminar structure including at least one die pad having a first die pad surface configured to mount a semiconductor chip;
pre-mold material molded onto the sculptured electrically conductive laminar structure, wherein the pre-mold material penetrates into said spaces and provides a laminar pre-molded substrate including said first die pad surface left exposed by the pre-mold material with the periphery of the at least one die pad bordering on the pre-mold material molded onto the sculptured electrically conductive laminar structure; and
wherein the periphery of the at least one die pad includes at least one stress-relief curved portion that borders on the pre-mold material molded onto the sculptured electrically conductive laminar structure over a smooth surface, the at least one stress-relief curved portion preferably extending in the plane of the laminar pre-molded substrate along an approximately sinusoidal trajectory.

11. The substrate of claim 10, wherein the at least one stress-relief curved portion comprises a protrusion extending into the pre-mold material molded onto the sculptured electrically conductive laminar structure.

12. The substrate of claim 11, wherein the protrusion includes at least one aperture therein, the at least one aperture filled by the pre-mold material molded onto the sculptured electrically conductive laminar structure.

13. The substrate of claim 10, wherein said at least one stress-relief curved portion of the at least one die pad at is positioned at a location of said sculptured electrically conductive laminar structure where a T-shaped space is provided filled by the pre-mold material molded onto the sculptured electrically conductive laminar structure.

14. The substrate of claim 10, wherein the at least one die pad of the sculptured electrically conductive laminar structure comprises a pair of neighboring die pads having a strip of pre-mold material therebetween, and wherein there is, in said pair of neighboring die pads, an alternation of said stress-relief curved portions.

15. The substrate of claim 14, wherein the alternation of said stress-relief curved portions provides interdigitated stress-relief curved protrusions.

16. The substrate of claim 14, wherein said strip of pre-mold material between the pair of neighboring die pads has a serpentine pattern.

17. The substrate of claim 10, wherein the at least one die pad has a second die pad surface opposite said first die pad surface, wherein the at least one stress-relief curved portion is provided at only one of the first die pad surface and the second die pad surface.

18. The substrate of claim 17, wherein the periphery of the other of the first die pad surface and the second die pad surface, opposite said at least one stress-relief curved portion, is rectilinear.

19. A semiconductor device, comprising:
a substrate according to claim 10; and
at least one semiconductor integrated circuit chip mounted on said first die pad surface.
